(19) United States
(12) Patent Application Publication
(10) Pub. No.: US 2003/0107097 A1
(43) Pub. Date: Jun. 12, 2003

(54) Ultra-rugged biometric I.C. sensor and method of making the same

(76) Inventors: Douglas C. McArthur, San Jose, CA (US); Thomas l. Andrade, Los Gatos, CA (US); John E. Meyer, Saratoga, CA (US)

Correspondence Address: LYON & LYON LLP, 633 WEST FIFTH STREET, SUITE 4700, LOS ANGELES, CA, 90071, US

(21) Appl. No.: 10/191,394

(22) Filed: Jul. 1, 2002

Related U.S. Application Data
(63) Continuation of application No. 09/354,386, filed on Jul. 14, 1999, now abandoned.

(51) Int. Cl. H01L 27/14; H01L 29/82

(52) U.S. Cl. 257/414; 257/415; 257/417; 257/418

(57) ABSTRACT

An ultra-rugged biometric integrated circuit sensor and method for constructing the same is provided. The sensor comprises a sensing area and a control electronics area, and, as result of its construction, the sensor has a topology whereby the sensing area is elevated with respect to the control electronics area. In other words, a depression is created on the sensor surface that allows the control electronics to escape damaging impacts by external forces. According to one embodiment, the sensing area and control electronics area are structures such there is no overlap between either area, except where the sensing area is electrically coupled to the control electronics. According to another embodiment, the sensor further comprises a electric static discharge structure that creates a least resistant path to ground. The electric static discharge structure further protects the control electronics from high voltage surges encountered in normal operation.

### CROSS-REFERENCE TO RELATED APPLICATION

This application is a continuation of U.S. patent application Ser. No. 09/354,386, filed Jul. 14, 1999, entitled “A Method Of Constructing An Ultra-Rugged Biometric I.C. Sensor”, which is incorporated herein by reference in its entirety and to which priority is claimed under 35 U.S.C. § 120.

### BACKGROUND

1. Field of the Invention

This invention relates to biometric integrated circuit (I.C.) sensors. More particularly, this invention relates to methods of constructing an ultra-rugged biometric I.C. sensor and structures thereof.

2. Background Information

Biometric identification is used to verify the identity of a person by digitally measuring selected features of some physical characteristic and comparing those measurements with those filed for the person in a reference database, or sometimes on a smart card carried by the person. Physical characteristics that are being used include fingerprints, voiceprints, the geometry of the hand, the pattern of blood vessels on the wrist and on the retina of the eye, the topography of the iris of the eye, facial patterns and the dynamics of writing a signature and typing on a keyboard.

The fingerprint is one of the most widely used physical characteristics in biometric identification. One way to measure and digitize a fingerprint is by using a semiconductor chip called a biometric chip in which the surface of the chip directly interfaces with its external environment, e.g. the chip directly touched by a finger. A gene chip is another example of biometric chip on which blood is dropped or squirted which then identifies the genetic code or genetic pattern of the sampled blood.

In the traditional semiconductor field, efforts have been made to protect the semiconductor chip and its internal circuitry from mechanical and electrical damages caused by direct contact with its external environment, such as a hand directly touching the chip or electric static discharges (ESD) caused by such touching. However, in the case of biometrics, the chip does not operate unless it is in direct contact with its external environment, e.g., directly touched by a finger.

A semiconductor solid state device which has its surface open to the external environment is susceptible to mechanical damage caused by objects that come into direct contact with the open surface of the chip as well as electrical damages caused by ESD events. Mechanical damage may be caused by horizontal movement of an object on the surface of the chip or vertical force applied to the surface of the chip. Efforts have been made to make the surface of a biometric chip resistant to horizontal movement of an object on the surface of the chip. U.S. patent Ser. No. 08/899,735 (hereafter, the '735 application), entitled “Electronic Apparatus Having Improved Scratch and Mechanical Resistance”, discloses such a scratch-resistant I.C. chip surface. The '735 application discloses a scratch resistant I.C. chip surface formed by leaving out the top aluminum layer in a conventional top metal stack which is typically made of titanium (Ti), titanium nitride (TiN) and aluminum (Al).

To make a scratch resistant I.C. chip surface, the surface material must be a hard material and is resistant to chemical penetration. Because aluminum is a very soft material while titanium nitride is a hard material, by eliminating the top aluminum layer from a conventional Ti—TiN—Al metal stack, a very hard and scratch resistant surface is formed by having the titanium nitride layer as the top surface layer. Experiments have shown that the surface of the finished device must also be very planar so that a horizontal movement of an object does not get caught by a helix or a bump on the surface, thereby damaging the electronic circuitry underneath.

A more germane concern, however, is the damage caused by a vertical force applied to the open surface of the biometric chip. An object may be inadvertently dropped onto the surface of the chip. People may inadvertently tap the surface of the chip. Vertical forces may also be caused by metal particles accelerating into the surface of the chip in an ultrasonic bath after soldering, if the particles are small enough to cause a large force per unit area.

A dropped object or a tap generally comes into contact with the highest portion of the surface first. An I.C. chip generally has a surface topography where the control electronics areas have higher topography than the sensing areas. The control electronics area includes circuitry for controlling and reading elements in the sensing area. The sensing area includes sensing elements such as a capacitor plate.

The vertical force from the dropped object or the tap comes into contact with the area containing the control electronics first and causes cracks in the conductive lines as well as the dielectric layer between the conductive lines. Metal extrudes from the conductive lines making up the control electronic circuitry into the cracks in the dielectric layer to cause microshorts between the various conductive lines. In a capacitive sensor where each pixel on a display is a signal received from a capacitor and generated by its associated control electronics, black lines or single black pixels appear at the display due to such shorts. Because the capacitor is very small in size as compared to, e.g., the tip of a pen, a vertical force applied to the surface of the sensor generally affects multiple pixels. In worst cases, the entire display goes black.

Similar damages may be caused by ESD events when certain objects come into contact with the device. In standard I.C. technology, ESD protections are only applied to the external leads of the device, which are electrically connected to the bond pads on the I.C. chip. ESD events at other parts of the device generally are not a concern because the I.C. chip is typically enclosed in a package having a thick insulating plastic cover that is sufficient to protect the internal circuitry from a large surge of current caused by an ESD event. However, in the biometric I.C. field, the I.C. chip must come into direct contact with its external environment, rather than being completely enclosed in a plastic package. Hence, the internal circuitry of a biometric chip is more susceptible to damages caused by ESD events because the surface of a biometric I.C. is not protected. The large surge of current caused by an ESD event may enter and flow through the conductive lines, melting, or even evaporating the conductive lines, thereby causing disconnects in the internal circuitry.

Therefore, what is needed is a rugged biometric I.C. chip that is capable of withstanding the application of vertical and horizontal forces, as well as capable of withstanding ESD events.

### SUMMARY OF THE INVENTION

In accordance with the present invention, structures and methods are provided to ruggedize a biometric chip by reversing the topology of a conventional biometric chip and providing ESD protections through an ESD routing structure. The biometric chip having a reversed topology has electrically insensitive areas, i.e., sensing areas, at a higher topology than the control electronics areas so that the electrically insensitive areas are the first points of contact when a vertical force is applied to the surface of the chip.

A thick dielectric layer is deposited over a conductive line. The thick dielectric layer has a thickness that allows the formation of a depression above the conductive line. In one embodiment, the thick dielectric layer comprises a material selected from the group consisting of silicon carbide, diamond, aluminum oxide and silicon nitride. A photoresist layer is applied and etched to form a mask defined by the conductive line to define the area of depression. The thick dielectric layer is then etched back at the depressed area. Next, the mask is removed after the reverse topology dielectric etch.

A spin-on-glass (SOG) planarization is applied to the resulting structure. A conductive material is deposited and patterned to form one plate of a capacitor. The device is then passivated with a passivation material which is also the dielectric for the capacitor. By doing a reverse topology dielectric etch, the capacitor plate is at a higher topology then the control electronics area. The capacitor plate interfaces with the circuitry in the electronics area at the depressed area.

In one embodiment, no control electronics are below the capacitor plate except where the capacitor plate is depressed to connect with the control electronics. This design rule prevents damage to the control electronics when a vertical force is applied at the capacitor plate area.

In one embodiment, a plate for active cancellation of stray capacitance is formed between the substrate and the capacitor plate at the sensing area. The plate comprises a material having similar hardness as the capacitor plate. In one embodiment, the plate comprises a hard material such as polysilicon, titanium or titanium nitride.

In one embodiment, the number of stacked conductive layers is reduced. For example, in one embodiment, at most two conductive layers are stacked in any region. This design rule allows a decrease to the overall height at the control electronics area, allowing further reversal in topology.

In one embodiment, ESD protection structures (i.e., ESD pillars) are formed throughout the sensing element array, for example, at a midpoint of four sensing elements. In one embodiment, the surface of the ESD pillar is exposed to external environment. The ESD pillar provides a least resistive path to ground so that during an ESD event, the large surge of current will enter the ESD pillar to ground, thereby protecting the control electronics in the device.

### BRIEF DESCRIPTION OF THE DRAWINGS

FIG. 1 shows a fingerprint sensing device and the ridge lines of a finger.

FIG. 2 shows a device having a topology where the control electronics area has a higher topography then the sensing area.

FIG. 3 shows a damaged device of FIG. 1.

FIGS. 4-9 show process steps forming a device having reversed topology.

FIG. 10 shows a prior art layout where various conductive lines cross over each other.

FIG. 11 shows a layout in accordance with the present invention, where no control electronics are under the capacitor plate except where the capacitor plate is depressed to connect with the control electronics, and at most two conductive layers are stacked at any region.

FIG. 12A shows a sensing element array having an ESD pillar at every midpoint of four sensing elements.

FIG. 12B shows a sensing element array having every four sensing elements having their own ESD pillar at their midpoint.

FIGS. 13-16 show process steps of forming an ESD pillar.

FIG. 17 shows a cross-sectional view of one embodiment of the ESD pillar.

FIG. 18 shows a cross-sectional view of another embodiment of the ESD pillar.

### WRITTEN DESCRIPTION OF THE PREFERRED EMBODIMENTS

The following specification describes a fingerprint acquisition sensor. However, this example is meant to be illustrative only. Other embodiments of this invention will be obvious in view of the following description to those skilled in the semiconductor processing arts. For instance, this invention is also applicable to other types of biometric sensors for sensing e.g., palm prints, blood, or other bodily fluids. In general, sensors with applications that require direct exposure to their external environment may employ this invention.

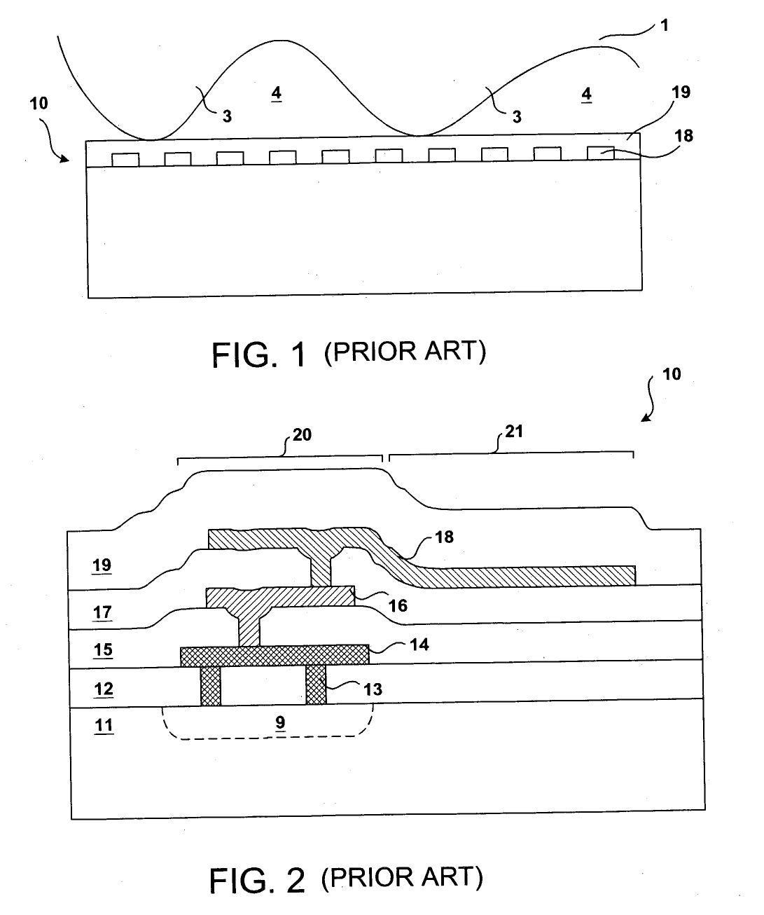

FIG. 1 shows a fingerprint acquisition sensor 10 and the ridge lines of a finger 1. When finger 1 at a known potential such as ground is brought into contact with passivation layer 19, the capacitance on capacitor plates 18 change. Because the surface of finger 1 (or another body part of a person) is uneven, the fingerprint is composed of ridges of skin that act as electrodes which are detected capacitively. With “ridges” 3 and “valleys” 4, the capacitance between each capacitor plate 18 and finger 1 varies in accordance with the topography of the surface of the skin. It is noted that capacitor plates 18 are smaller than ridges 3 and valleys 4. In one embodiment, capacitor plate 18 has a dimension of approximately 37 μm by 42 μm.

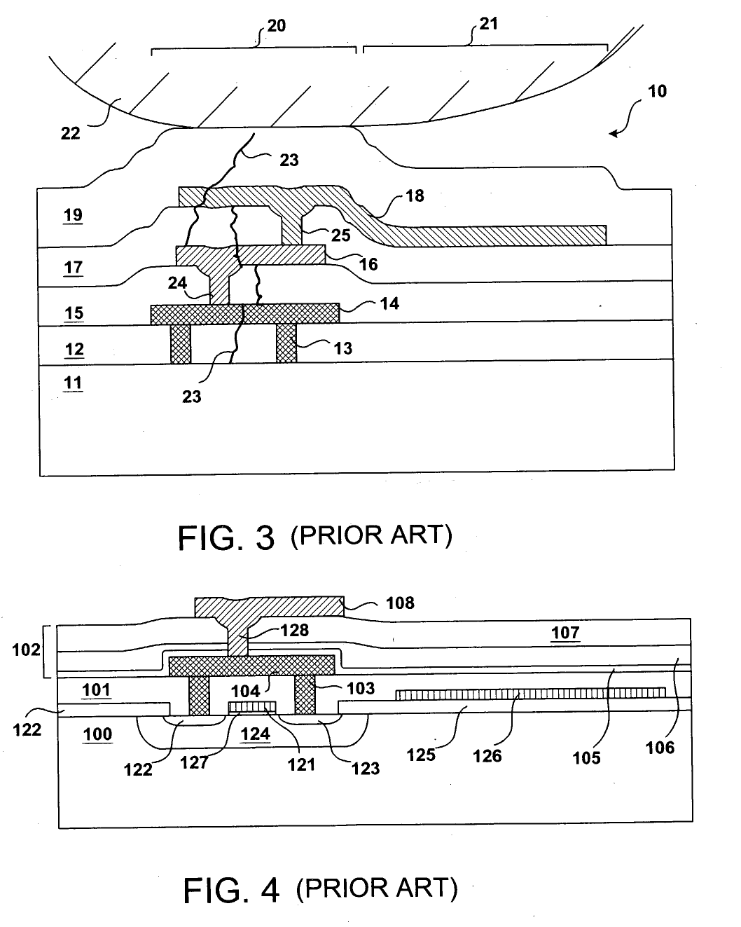

FIG. 2 shows a cross-sectional view of an undamaged capacitive fingerprint acquisition sensor 10 with conventional topography. Capacitive fingerprint acquisition sensor 10 has a sensing area 21 and a control electronics area 20. Sensing area 21 includes a capacitor plate 18. Capacitor plate 18 is covered by a passivation layer 19. Capacitor plate 18 has the highest topology where it connects to the control electronics area 20. Control electronics area 20 contains devices and circuits for controlling and reading sensing elements in sensing area 21. In one embodiment, the various capacitances measured are converted into electrical signals which are used to construct a fingerprint on a display. The control electronics area 20 is constructed from various conductive lines 14 and 16, contacts 13, polysilicon lines (not shown) and active/passive devices (not shown) in area 9 in substrate 11. The devices can be resistors, transistors, and the like.

As can be seen from FIG. 2, control electronics area 20 has a higher topology than sensing area 21. When an object comes into contact with the surface of capacitive fingerprint acquisition sensor 10, the highest area, i.e., control electronics area 20, is the first point of contact and receives the highest stress from the force. As a result, the fractures and damages would occur at control electronics area 20, as is discussed below.

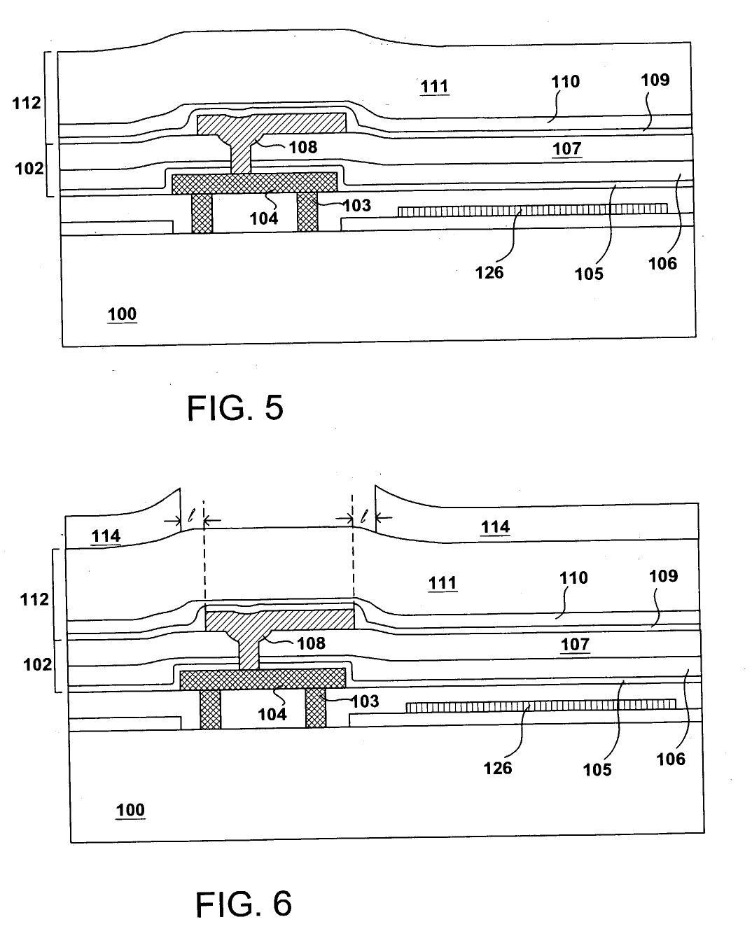

FIG. 3 shows a cross-sectional view of a damaged capacitive fingerprint acquisition sensor 10 of FIG. 1. An object 22 comes into contact with the highest area, i.e., control electronics area 20, first. The vertical force exerted by an object 22, applied at control electronics area 20 causes cracks 23 throughout capacitive fingerprint acquisition sensor 10. The vertical force is evenly distributed in and evenly supported by all the materials underneath the point of force application. The degree to which a material can withstand mechanical stress depends on that material's hardness. Typical material hardness is expressed as Knoop hardness, in units of kg/mm², or Youngs Modulus, expressed in units of dyne/cm². With respect to semiconductor devices, the degree to which a particular region of a semiconductor device can withstand localized pressure or force is a function of the materials making up that region of the semiconductor device and their respective material hardness.

In FIGS. 2 and 3, the surface layers comprise passivation layer 19 which is typically made of silicon nitride (Si₃N₄) and capacitor plate 18 which is typically made of titanium nitride (TiN). Silicon nitride and titanium nitride exhibit Knoop hardness in the range of 1,500-3,000 kg/mm². The underlying dielectric layers 12, 15, and 17 are typically made of silicon dioxide (SiO₂) which has a typical hardness of 800-1000 kg/mm². The underlying interconnects 13, 14, and 16 are typically made of aluminum which has a very low hardness value of approximately 150 kg/mm² .

When a localized surface force is applied to a region over an interconnect 13, 14, or 16, the softer interconnect material may deform, migrate or extrude, resulting in fractures or cracks in dielectric layers 12, 15, and 17, and passivation layer 19, which lead to possible electrical shorts between conductive lines 14, 16, and 18. Specifically, the force exerted by object 22 causes conductive line 16 to deform and this results in cracks 23 through dielectric layer 17. The force extends beyond conductive line 16 and cracks dielectric layer 15 between conductive lines 16 and 14. Similarly, conductive line 14 may deform and results in further cracks 23 in dielectric layer 15 and electrically insulating layer 12. Metal stringers (not shown) extend into cracks 23, thereby causing short circuits between conductive lines 16 and 14. In addition, due to the deformation and fractures underneath, capacitor plate 18 and passivation layer 19, which are relatively hard, may also fracture.

In the layout shown in FIGS. 2 and 3, the highest area in the topography is caused by stacked interconnects 13, 14, and 16 that make up the control electronic circuitry and capacitor plate 18. Control electronic circuitry are active areas. However, most of the surface area of the I.C. chip 10 is sensing areas 21 made of capacitor plates 18, which are passive devices. Therefore, sensing areas 21 are better areas to receive vertical forces because they comprise harder materials and are passive devices. By raising sensing areas 21,, the mechanically hardest areas would come into contact with the vertical force first, minimizing damages to capacitive fingerprint acquisition sensor 10.

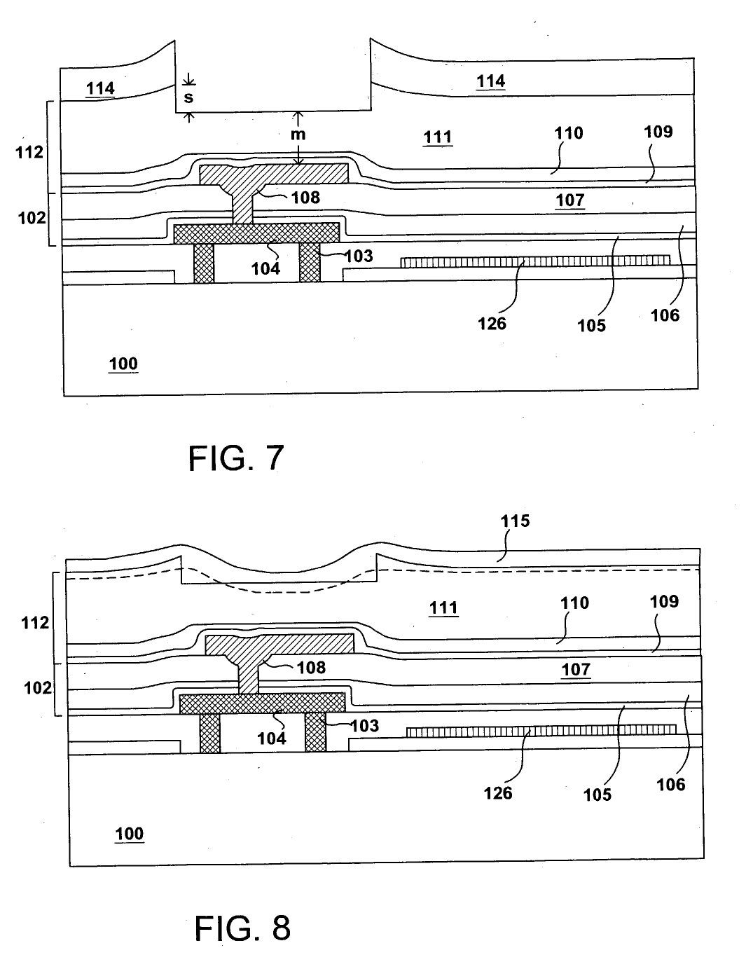

FIGS. 4 through 9 show process steps for forming a device having reversed topology, i.e. having a higher sensing area than the control electronics area. Referring to FIG. 4, a substrate 100 is provided. Substrate 100 is typically a semiconductor substrate for forming active and passive devices such as transistors, capacitors and resistors. Some examples of semiconductor substrate materials are silicon, silicon germanium and gallium-arsenide. Other substrates used for a flat panel display may be utilized if desired.

The active and passive devices are formed through standard semiconductor processing techniques including the definition of N-well and P-well regions, field oxide regions (LOCOS), and N+ and P+ junction regions, for example. Field oxide region 125 is formed over substrate 100. After formation of field oxide region 125, a polysilicon layer is deposited and patterned through standard photolithography. The polysilicon layer deposited on a gate oxide 127, residing in the active device window formed in field oxide region 125, forms a polysilicon gate 121. Thus, FIG. 4 shows an active device, e.g., a transistor, comprising a polysilicon gate 121 and junctions 122 and 123 in a P-well 124. It is noted that the transistor will not be shown in the subsequent figures for simplicity.

In one embodiment, the polysilicon layer is deposited over field oxide region 125 to form an optional plate 126. Plate 126 is for active cancellation of stray capacitance between a subsequently formed capacitor plate 116 (see FIG. 9) and substrate 100. Stray capacitance decreases resolution of the sensor. Therefore, it is desirable to eliminate such capacitance. In the alternative, plate 126 can be made of any hard conductive materials such as, but not limited to, titanium and titanium nitride. Plate 126 is approximately the same size as the subsequently formed capacitor plate 116. It is noted however that since force is equally distributed and supported by all components, if capacitor plate 116 has a greater hardness, plate 126 is likely to be damaged first, creating shorts. On the other hand, if plate 126 is made of a harder material, capacitor plate 116 would be damaged first, in which case, the pixel would be affected. Therefore, the most efficient way of construction is to make capacitor plate 116 and plate 126 of materials with the same or similar hardness.

An electrically insulating layer 101 is formed on top of substrate 100, gate 121, plate 126 and field oxide region 125 to isolate conductive lines 104 from the active devices contained in substrate 100 and plate 126 below. Electrically insulating layer 101 is made of any incompressive electrically insulating materials such as, but not limited to, silicon dioxide (SiO₂) . Electrically insulating layer 101 is patterned using a conventional photolithography process to form contact holes, e.g. by depositing a photoresist layer; patterning the photoresist layer into a mask; and etching the exposed electrically insulating layer 101. A contact material is deposited over electrically insulating layer 101 and into the contact holes. The contact material is planarized using a well known etch back technique such as reactive ion etching (RIE) to form contacts 103. Contacts 103 provide electrical paths from the active devices in substrate 100 to subsequent conductive lines, such as conductive lines 104. Contacts 103 typically comprise a low electrical resistance material or alloy such as tungsten, aluminum, copper, silver, gold and their alloys.

Next, a conductive material is deposited over contacts 103 and electrically insulative layer 101. The conductive material is typically aluminum (Al) or aluminum copper alloy (AlCu) but can be other conductive materials as well. In one embodiment, the conductive material is a 300 Å titanium nitride (TiN) layer over a 5000 Å aluminum copper (AlCu) alloy layer. A photoresist layer (not shown) is deposited over the conductive material and patterned to define conductive lines 104. The exposed portions of the conductive material are then etched to form conductive lines 104.

Dielectric layer 102 is formed over conductive lines 104 and into the regions between conductive lines 104 and 108. Dielectric layer 102 is typically made of a 5000 Å plasma enhanced chemical vapor deposition (PECVD) oxide layer 107 over a spin on glass (SOG) coating 106 over a 2000 Å PECVD oxide layer 105, but can be made of other insulating materials. SOG layer 106 can be made of any type of SOG or flowable oxide. In one embodiment, SOG layer 106 is made of Silicate SOG, which is phosphosilicate dissolved in an alcohol solvent. In another embodiment, SOG layer 106 is made of Siloxane SOG, which is methylsiloxane dissolved into an alcohol solvent. In yet another embodiment, SOG layer 106 is made of FOX (flowable oxide), which is an inorganic solution of hydrogen-silsesquioxane dissolved in a siloxane solvent. SOG layer 106 is then etched back and cured. SOG layer 106 is implanted for ionic barrier integrity.

A photoresist layer (not shown) is formed over dielectric layer 102 and patterned to define the locations of via 128. The exposed portion of dielectric layer 102 is then etched to form via 128 for electrical conductivity between electrically conductive layer 104 and a subsequent electrically conductive line 108.

Next, a conductive material is deposited over dielectric layer 102 and into vias 128. The conductive material is then patterned using conventional lithography process to form conductive lines 108. Conductive lines 108 are made of, for example, a 1000 Å titanium (Ti) layer over a 6000 Å aluminum-copper alloy (AlCu) layer over a 300 Å titanium nitride (TiN) layer. In this embodiment, the process up to this point is that of a conventional process. It is noted that although only two layers of conductive lines are shown, there can be additional layers of conductive lines.

FIG. 5 shows a dielectric layer 112 formed over dielectric layer 102 and conductive lines 108. Dielectric layer 112 is formed of a very thick dielectric layer 111 over a SOG coating 110 over a dielectric layer 109. Dielectric layers 109 and 111 are made of a material such as tetraethyl orthosilicate (TEOS), or PECVD oxide.

A coat of spin on glass (SOG) 110 is spun over dielectric layer 109 and cured. SOG layer 110 can be made of any type of SOG or flowable oxide, such as Silicate SOG, Siloxane SOG, or FOX (flowable oxide). SOG layer 110 is then etched back so that a continuous thin film remains between dielectric layer 109 and the subsequent dielectric layer 111.

The very thick dielectric layer 111, e.g. 14,000 Å of tetraethyl orthosilicate (TEOS), is deposited conformally over SOG layer 110 by, e.g., plasma enhanced chemical vapor deposition (PECVD). Dielectric layer 111 is of a thickness that can be used to create depressions above conductive lines 104 and 108.

To obtain a scratch resistant surface, the thick dielectric layer 111 can be planarized to eliminate bumps and to create a flat surface. The flat surface results in mechanical insensitivity to horizontal movements of an object on the surface of the sensing device.

To obtain a tap resistant device, however, a reversed topology is created. In FIG. 6, a photoresist layer is applied and patterned using conventional photolithography process to create a mask 114. Mask 114 defines the regions where the depressions will be, and is defined by conductive lines 108. Mask 114 has a bias 1 on either side of conductive lines 108 above which the depression will be made. Bias 1 is for ease of design fabrication and is a function of the SOG slope. For example, bias 1 is set at a distance where most of the “roll-off” has occurred, typically at approximately +0.6 μm to +0.8 μm.

As is shown in FIG. 7, dielectric layer 112 is then etched using a dry etching technique such as, but not limited to, plasma etching or reactive ion etching (RIE) until an etch distance s is reached. Distance s is called the etch step height. A remaining thickness m of dielectric layer 111 is left over conductive lines 108. The sum of distance s and thickness m is equal to the deposited dielectric thickness of dielectric layer 111, the underlying dielectric layer 109 and SOG coating 110. Distance s and thickness m are determined by a predetermined etch time, the amount of dielectric layer 112 etched being proportional to the time of the etch. The greater the amount of dielectric layer 112 is etched, i.e., more reversed topology, the greater distance s is obtained. The maximum amount of this reverse topology dielectric etch is determined by the original amount of the dielectric material deposited because conductive line 108 cannot be exposed.

Dry etching is an anisotropic etch and has a high selectivity with respect to mask 114. As a result, the reverse topology dielectric etch produces very sharp edges and steep sidewalls in dielectric layer 112 where the edges of mask 114 are, as shown in FIG. 7. The sharp edges are undesirable because a subsequent conductive layer deposited over the composite structure, over the sharp edges and continuing over the steps and the steep sidewalls may become too narrow and cause electrical disconnects. Therefore, after mask 114 is removed, a SOG planarization is carried out.

Turning to FIG. 8, SOG layer 115 is applied over dielectric layer 112. SOG layer 115 can be made of any type of SOG or flowable oxide such as, but not limited to, Silicate SOG, Siloxane SOG, and FOX. SOG layer 115 is cured and partially etched back by a dry etch so that SOG remains only in the troughs, smoothing out the sharp edges caused by the reverse topology dielectric etch, as shown by the dotted line in FIG. 8. The sharp edges of dielectric layer 111 are also etched in this process.

Referring to FIG. 9, a via 117 is formed through standard photolithographic technique to enable an electrical contact between subsequent deposited conductive layer 116 and underlying conductive line 108. A conductive material is deposited over dielectric layer 112 and the remaining SOG 115 in the troughs (224), and into via 117. The conductive material is a stack made of, but not limited to, an 1800A titanium nitride layer over 200 Å titanium layer. The conductive material is then patterned using conventional photolithography process to form a capacitor plate 116.

Next, the device is passivated with a passivation material to a thickness of, e.g., approximately 2000 Å-12,000 Å. Passivation layer 118 is a low stress compressive material having a tensile strength of, e.g. −1 to −2×10⁹ Dyne/cm². A low stress compressive material is used for passivation layer 118 because high stress tensile materials tend to crack and high stress compressive materials tend to peel off. Passivation layer 118 also acts as a dielectric between capacitor plates 116 and a finger.

It is noted that although the reverse topology dielectric etch described above is carried out at the dielectric layer immediately below the passivation layer, it is possible to carry out the reverse topology dielectric etch at one or more other dielectric layers. However, additional limitations will normally be required. For example, all the conductive lines typically must coincide, i.e., be lined up, and the upper conductive lines typically must be equal to or smaller than the width and length of the conductive lines below.

To further strengthen a biometric sensor, the passivation material that forms the surface of the sensor needs to be a robust material. In addition, the material should be able to be deposited with chemical vapor deposition (CVD) techniques or a method that is compatible with silicon processing., The material should also be impervious to chemicals, e.g., chemical penetration.

Examples of passivation layer 118 materials that satisfy the above conditions are PECVD silicon nitride (Si₃N₄), silicon carbide (SiC), aluminum oxide (Al₂O₃) and diamond (C). Silicon nitride exhibits Knoop hardness of 1,500-3,000 kg/mm². Silicon carbide exhibits Knoop hardness of 5,000-8,000 kg/mm² and has the characteristics of being robust and impervious to chemicals such as acid. Aluminum oxide exhibits Knoop hardness of 6,000-9,000 kg/mm². Diamond exhibits Knoop hardness of 8,000-10,000 kg/mm².

With a reversed topology, the surface topography includes a depression (223) at the control electronics area (220) while the sensing area (221), which is the most mechanically robust region, has the highest topology of the sensing device. Hence, the sensing area (221) would be the first point of contact when a foreign object comes into contact with the device, resulting in better mechanical resistance to a vertical force than the conventional topography shown in FIG. 2.

Referring back to FIG. 2, the prior art surface topography includes a large bump at control electronics area 20. When an object is dropped, it will come into contact with this large bump first, causing damages to the control electronics underneath as shown in FIG. 3.

The reversed topology also results in better scratch resistance than the prior art surface topography because a large bump is more susceptible to damages caused by a horizontal force than a flatter surface resulted from a reversed topology. When a horizontal force is applied to the surface, the horizontal force is more likely to be obstructed by the large bump, causing damages to the control electronics. On the other hand, with the structure shown in FIG. 9, an abrasive force tends to damage only the edge of the capacitor plate rather than the entire capacitor plate. Hence, the structure shown in FIG. 2 is more susceptible to abrasion failures as well as tap failures than the structure shown in FIG. 9.

To further improve the mechanical robustness of sensing area 21, in one embodiment, control electronics below capacitor plate 116 are eliminated, except where capacitor plate 116 is depressed to connect with the control electronics, e.g., conductive lines 104 and 108. As described above, damages to the control electronics area (220) are initiated when soft materials, e.g., materials making up the conductive lines, are present at the point of force application because force is evenly distributed and supported by all the materials underneath. Therefore, when a force is applied at the capacitor plate 116 area, the soft materials underneath may deform and cause the dielectrics to crack, thereby causing electrical shorts between conductive lines or between conductive line and capacitor plate. Hence, by eliminating control electronics below capacitor plate 116, the electrical shorts caused by damaged conductive lines in the sensing area are effectively eliminated.

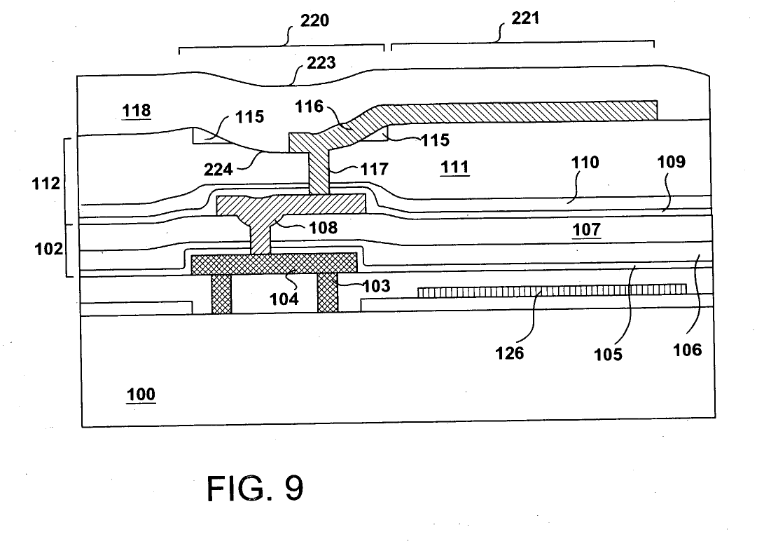

FIG. 10 shows a conventional layout where various conductive layers cross over each other. In the capacitor plate 18 area, control electronics such as conductive lines 14 and conductive lines 16 may be under capacitor plate 18. For example, in area 27, capacitor plate 18 crosses over conductive lines 14; in area 28, capacitor plate 18 crosses over conductive lines 16; and in area 29, capacitor plate 18 crosses over polysilicon lines 30. The crossovers occur in areas other than area 31 where capacitor plate 18 is connected with the control electronics. Such a layout would result in a potential short when a vertical force is applied, as described above.

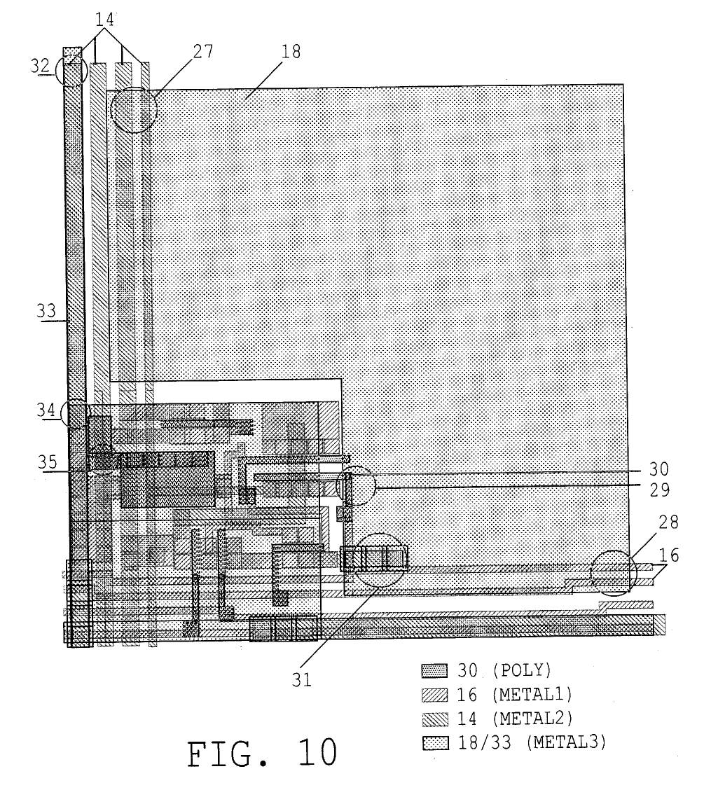

FIG. 11 shows a layout in accordance with the present invention. As can be seen from FIG. 11, except at regions 132 where capacitor plate 116 is connected with the control electronics, conductive lines 104 and conductive lines 108 do not cross over capacitor plate 116. This reduces the risk of damage to the control electronics when a vertical force is applied to the sensing device. It is noted that a plate 126 of approximately the same size as capacitor plate 116 is under capacitor plate 116. Plate 126 is for active cancellation of stray capacitance between capacitor plate 116 and substrate 100 (not shown) under plate 126. In general, plate 126 is made of a material that has a hardness similar to that of capacitor plate 116. Such material includes, but is not limited to polysilicon, titanium or titanium nitride.

Referring back to FIG. 10, the control electronics area outside of capacitor plate 18 includes areas where many conductive lines cross over. For example, in area 32, conductive plate 33 crosses over conductive line 14; in area 34, conductive plate 33 crosses over conductive lines 14 and 16; and in area 35, conductive plate 33 crosses over conductive line 14, conductive line 16 and polysilicon line 30. As described above, the highest areas in the sensor are caused by the stacking of conductive lines. Therefore, in one embodiment, the control electronics area is brought to a lower level than the level formed by using the reverse topology process described above alone, by decreasing the number of stacked conductive lines at any one region.

In a conventional layout as that shown in FIG. 10, conductive plate 33 is typically patterned from the same conductive layer that forms capacitor plate 18. Conductive plate 33 is used as a light blocker to prevent photons from reaching the semiconductor surface, thereby producing photo-current on the semiconductor surface. However, experiments have shown that conductive line 16 provides sufficient light blockage and thus, conductive plate 33 is unnecessary. Hence, conductive plate 33 can be eliminated from the control electronics area because it does not serve a useful function, thereby lowering the profile in the control electronics area.

To further lower the profile in the control electronics area, in one embodiment, at most two conductive lines are stacked in any one region. In the example shown in FIG. 11, at most two of the conductive line 104, conductive line 108 and polysilicon line 133 are stacked. For example, conductive line 104 and conductive line 108 are stacked (region 129); conductive line 104 and polysilicon lines 133 are stacked (region 130); and conductive line 108 and polysilicon lines 133 are stacked (region 131). However, conductive line 104, polysilicon line 133 and conductive line 108 are not stacked in the same region. It is noted that polysilicon lines 133 may be formed from the same layer that forms polysilicon plate 126. Therefore, through layout methodology, the difference in height between the control electronics area versus the sensing area can be further increased.

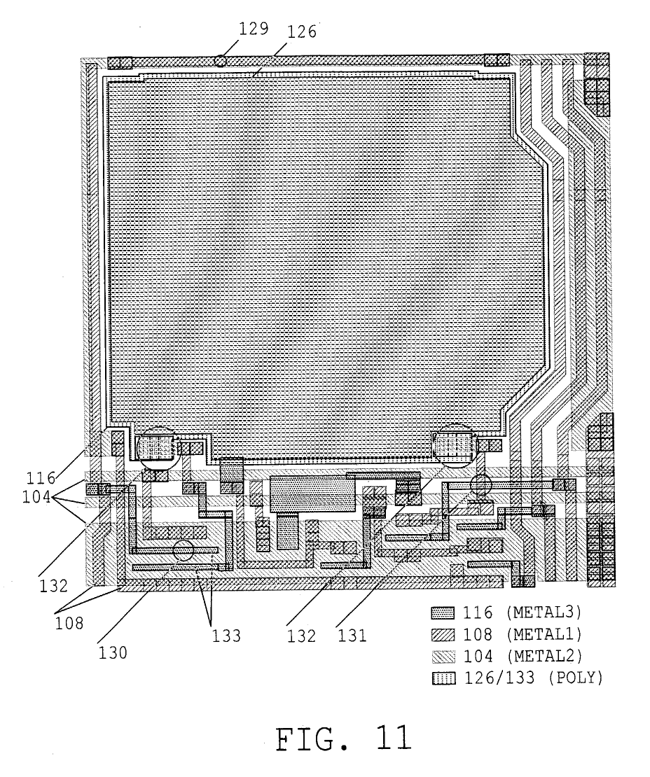

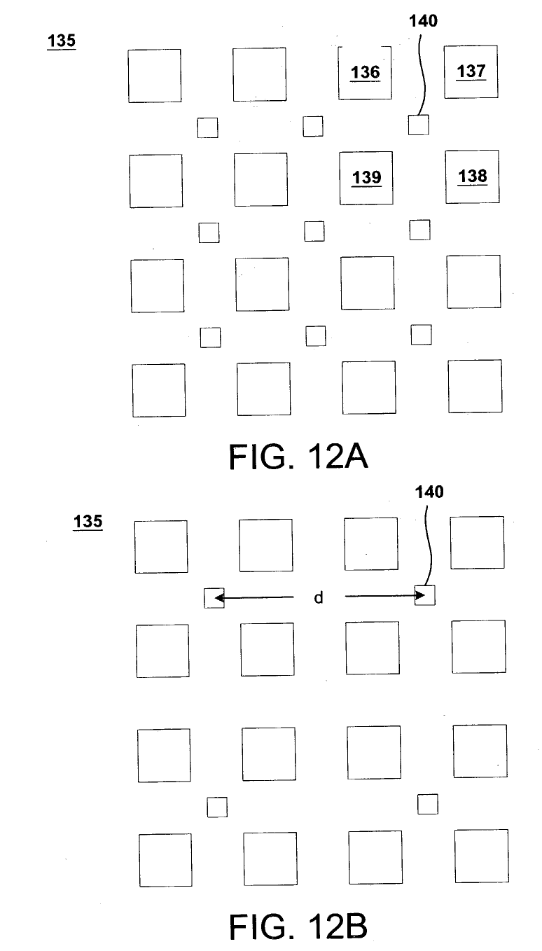

In one embodiment, electric static discharge (ESD) pillars are located throughout the sensing element array 135, as illustrated in FIGS. 12A and 12B. An example of the detailed view of each sensing element, e.g., 136, 137, 138 and 139, is shown in FIGS. 9 and 11, discussed above. Hence, the surface of the sensor array 135 is not smooth but is dimpled. For example, each sensing element in sensing array 135 has a depressed area where the control electronics are. As will be shown later, additional depressed areas may be created by the ESD pillars. Of course, sensing elements 136 through 139 may be other types of sensing elements such as, but not limited to, gene chip sensing elements.

FIG. 12A shows one embodiment where an ESD pillar 140 is formed at every midpoint between four sensing elements, e.g., sensing elements 136, 137, 138, and 139, in sensor array 135. Sensing elements are positioned, for example, approximately 2 μm to approximately 23 μm from each other and are configured in a quad pattern.

The general idea is to provide a structure that provides a most direct and least resistive electrical path to ground so that a large surface ESD current would be directed to ground as quickly as possible and away from the control electronics in the device. ESD pillar 140 generally includes various layers of conductive lines all connected together. The ESD pillar 140 is then connected to electrical ground. In one embodiment, the surface electrode, i.e., the topmost conductive line of ESD pillar 140, is square in shape, each side measuring 12 μm. ESD pillars 140 conducts the large surge of current caused by an ESD event, e.g., from a finger touching the sensing device, away from other circuitry in the sensing device by providing a direct electrical path to ground, thereby adding electrical ruggedness to the sensing device.

In the embodiment shown in FIG. 12B, ESD pillar 140 is implemented at every other midpoint, or every four sensing elements have their own ESD pillar formed at their midpoint. Alternatively, ESD pillars 140 may be formed at any midpoint or at any distance apart. In one embodiment, the center of each ESD pillar is at a distance d from the centers of other ESD pillars, wherein distance d is approximately 100 μm.

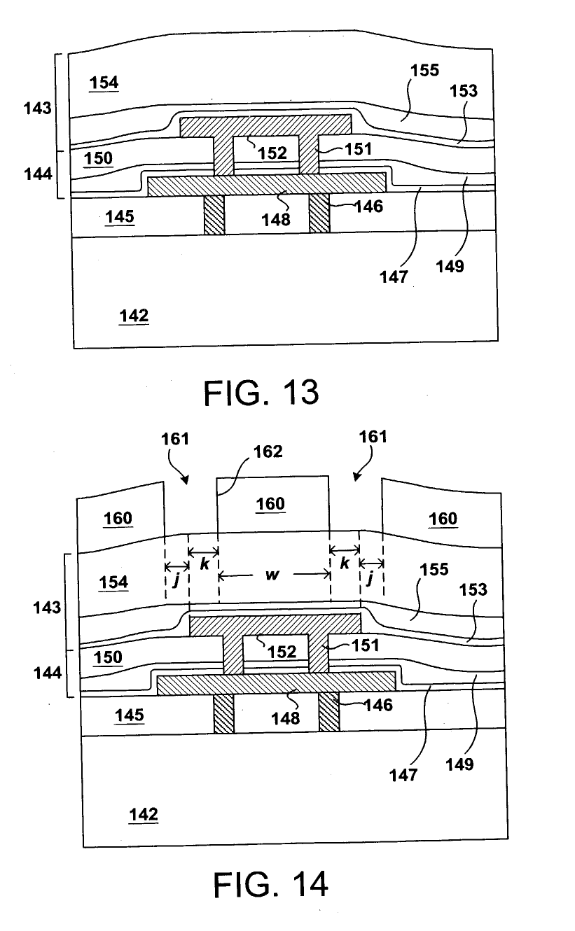

FIGS. 13-16 show process steps of forming an ESD pillar. In one embodiment, the method for constructing the ESD pillar is conventional up to conductive line 152 and is similar to that described above with respect to FIGS. 4 and 5. In particular, FIG. 13 shows an electrically insulating layer 145 formed on top of substrate 142 to isolate conductive line 148 from the active devices (not shown) contained in substrate 142 below. Electrically insulating layer 145 is patterned using a conventional photolithography process to form contact holes. A contact material is deposited over electrically insulating layer 145 and into the contact holes to form contacts 146. Next, a conductive material is deposited over contacts 146 and electrically insulating layer 145. A photoresist layer (not shown) is deposited over the conductive material and patterned to define conductive line 148. The exposed portions of the conductive material are then etched to form conductive line 148.

Dielectric layer 144 is formed over conductive line 148 and electrically insulating layer 145. Dielectric layer 144 includes a PECVD oxide layer 150 over a SOG coating 149 over a PECVD oxide layer 147. A photoresist layer (not shown) is formed on top of dielectric layer 144 and patterned to define the locations of vias 151. The exposed portion of dielectric layer 144 is then etched to form vias 151. Next, a conductive material is deposited over dielectric layer 144 and into vias 151. The conductive material is then patterned using conventional lithography process to form conductive line 152. In this embodiment, the process steps up to this point are that of a conventional process.

A dielectric layer 143 is formed over dielectric layer 144 and conductive line 152. Dielectric layer 143 is formed of a very thick dielectric layer 154 over a SOG coating 155 over a dielectric layer 153. Dielectric layer 154 is of a thickness that is capable of creating a reversed topology. For example, dielectric layer 154 is a 14,000 Å thick TEOS layer, formed over SOG layer 155 conformally.

FIG. 14 shows a photoresist layer 160 deposited over dielectric layer 154 and patterned using a conventional photolithographic technique to define the topography of the ESD pillar. Photoresist layer 160 is defined such that an opening 161 is created on either side of the underlying conductive line 152. Each opening 161 has a bias j extending beyond the outer edge of the underlying conductive layer 152 and a distance k between the outer edge of conductive line 152 and an edge 162 of photoresist layer 160. In one embodiment, bias j has the same distance as bias 1 in photoresist layer 114 shown in FIG. 6 for ease of construction. Bias j is defined as a function of the SOG slope as discussed above. The combined distance of bias j and distance k is a distance wide enough to allow a via to be created in dielectric layer 143 after the reverse topology dielectric etch using conventional photolithography. The photoresist layer 160 between openings 161 has a width w. Typical dimensions for widths j, k, and w are 0.60 μm, 3.00 μm, and 10.00 μm, respectively.

Dielectric layer 143 is then etched using a dry etching technique until an etch distance s is achieved, as shown in FIG. 15. Etch distance s is the same as etch distance s shown in FIG. 7 for ease of manufacturing but can be of a different distance. A remaining thickness m of dielectric layer 143 is left over conductive line 152 at opening 161. Photoresist layer 160 is then removed. A SOG planarization is performed as described above to smooth out the sharp edges caused by the reverse topology dielectric etch.

Referring to FIG. 16, vias 157 are formed through standard photolithographic technique to enable an electrical contact between subsequent deposited conductive layer 156 and underlying conductive layer 152. A conductive material is deposited over dielectric layer 143 and into vias 157. The conductive material is typically made of a stack of a 1800 Å titanium nitride layer over a 200 Å layer of titanium barrier metal. The conductive material is patterned using standard photolithographic technique to form a rectangular surface electrode 156. The surface electrode 156 can be of any shape. Surface electrode 156 can be at a position slightly higher than the surrounding capacitor array sensor plates in a reversed topology sensor if there are no conductive lines below the capacitor plates because the ESD pillar is formed by a number of stacked conductive lines. The ESD pillar as shown in FIG. 16 is made up of surface electrode 156, conductive line 152, conductive line 148 and contacts 146. The height difference, in one embodiment, is approximately 1000 Å. A surface passivation layer 158 is then deposited over surface electrode 156 and dielectric layer 143. The ESD pillar is grounded through substrate 142 which is grounded.

When an ESD event occurs, such as when a finger touches the sensing device, the ESD pillar provides a least resistant path to ground because the current needs only travel through passivation layer 158, conductive lines 156, 152 and 148, and contacts 146 to enter the ground. This is compared to other indirect paths (not shown) to ground which may include, for example, various dielectric layers, various conductive lines and active/passive devices. It is to be noted that although passivation layer 158 is insulative and has a high resistance, it is not critical because the current must pass through passivation layer 158 to reach ground in all areas. Therefore, so long as the ESD pillar provides a most direct and least resistive path to ground, the ESD pillar will direct the current away from other circuitry in the device.

As can be seen, the ESD pillar is constructed using the same processing sequence and materials as those used to construct the reversed topology sensor. Therefore, ESD pillars can be easily integrated and implemented into a reversed topology sensor, but do not have to be.

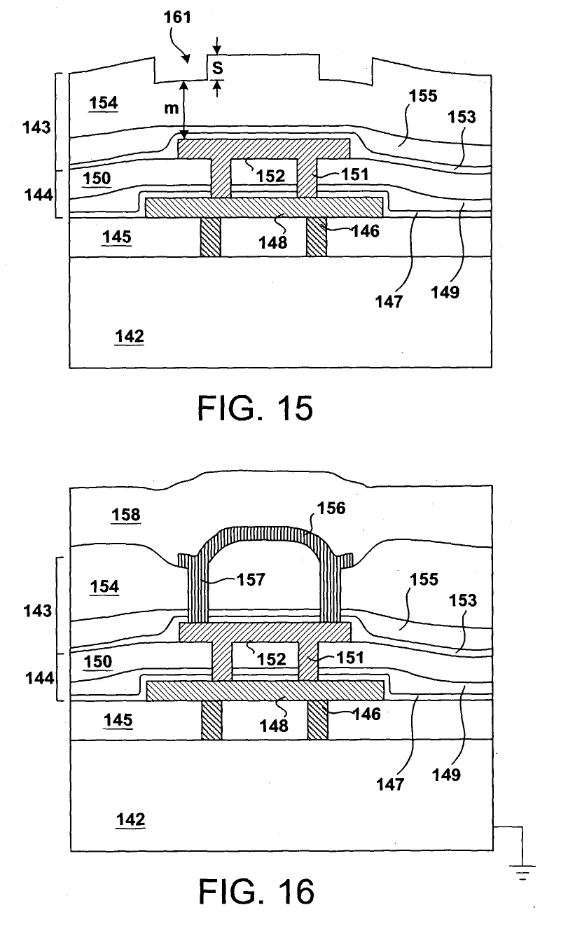

In one embodiment, passivation layer 158 is masked and etched to form an opening 159 directly over and exposing surface electrode 156, as shown in FIG. 17. This embodiment provides an even lower resistive path to circuit electrical ground by removing the highly resistive surface passivation layer 158. The minimum width of opening 159 is determined by the etching process which is approximately 0.5 μm. In one embodiment, opening 159 is approximately 6.0 μm wide. Because opening 159 is relatively small as compared to the entire sensor surface, opening 156 only affects the scratch resistance very insignificantly.

It is noted that the ESD pillar does not have to have the exact construction as that shown in FIGS. 16 and 17. For example, instead of two interconnects connecting the conductive lines, there may be only one interconnect. Another example would be instead of two conductive lines, there may be additional conductive lines. Other embodiments may include more than two interconnects connecting the conductive lines.

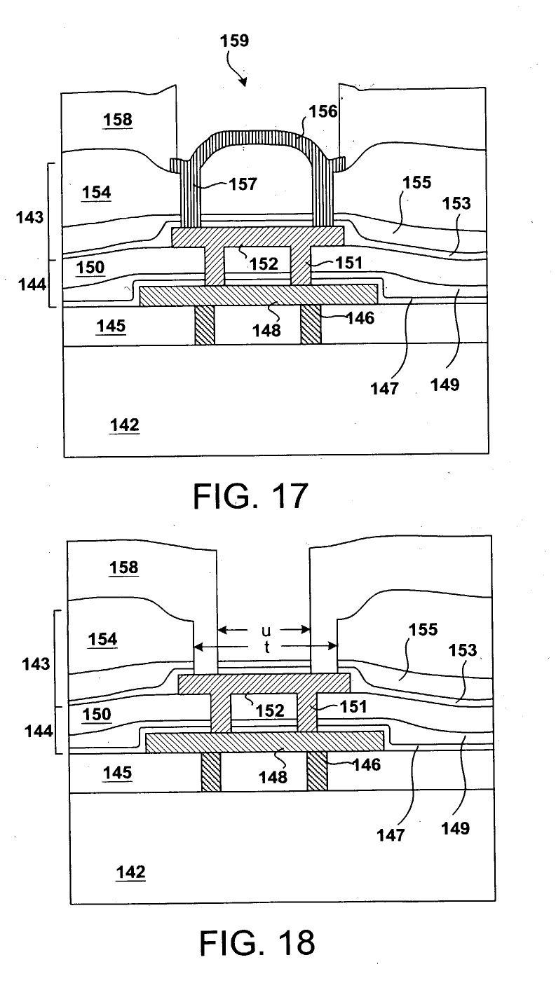

FIG. 18 shows another embodiment of the ESD pillar. In this embodiment, surface electrode 156 is eliminated and dielectric layer 143 is etched such that an opening is formed to expose a top surface portion of conductive line 152. The opening has a width t which is approximately 10 μm. The minimum width for the opening is dependent on the photolithography technique used and in one embodiment, is approximately 0.5 μm. The resulting device is then passivated with a passivation layer 158. Next, passivation layer 158 is etched to expose a top surface portion of conductive line 152. The exposed conductive line 152 has a width u which is approximately 6 μm. Width u is limited by the photolithography method used and the minimum dimension is approximately 0.5 μm.

What is claimed is:

1. A semiconductor device for biometric identification, comprising:
a rigid sensing area;
a control electronics area; and
at least one dielectric layer disposed in both said control electronics area and said sensing area, the dielectric layer including an etched region above said control electronics area, the etched region creating a higher topology in said sensing area than in said control electronics area.

2. The device of claim 1, further comprising:
a capacitor plate located in said sensing area; and
a circuit device located in said control electronics area;
wherein said sensing area and said control electronics area do not cross over, except where said capacitor plate is electrically coupled to said circuit device.

3. The device of claim 1, wherein said semiconductor device comprises:
a substrate;
an electrically insulating layer having a contact, said electrically insulating layer being formed over said substrate;
a first conductive line formed over said electrically insulating layer and said contact;
a first dielectric layer having a first via, said first dielectric layer being formed over said first conductive line and said electrically insulating layer;
a second conductive line formed over said first dielectric layer and into said first via;
a second dielectric layer having a second via, said second dielectric layer being formed over said first dielectric layer and said first conductive line;
a third conductive line formed over said second dielectric layer and said second conductive line; and a passivation layer over said third conductive line and said second dielectric layer.

4. The device of claim 1, wherein said sensing area comprises said third conductive line.

5. The device of claim 1, wherein said control electronics area comprises said contact, said first conductive line, and said second conductive line.

6. The device of claim 3, further comprising:
a fourth dielectric layer, beneath the second dielectric layer; and
wherein said second dielectric layer comprises:
a third dielectric layer, disposed over said fourth dielectric layer; and
a spin-on-glass coating disposed over said fourth dielectric layer.

7. The device of claim 3. wherein said passivation layer comprises a low stress compressive material.

8. The device of claim 3, further comprising a plate between said substrate and said third conductive line.

9. The device of claim 1, wherein said semiconductor device comprises a plurality of said rigid sensing elements.

10. The device of claim 9, further comprising an electric static discharge (ESD) structure between at least two of said rigid sensing elements.

11. A semiconductor device for biometric identification, comprising:
a rigid sensing area;
a control electronics area;
at least one dielectric layer disposed in both said control electronics area and said rigid sensing area, the dielectric layer including an etched region above said control electronics area; and
a passivation layer, disposed over said dielectric layer, wherein the etched region creates a higher topology in said rigid sensing area than in said control electronics area with respect to said passivation layer.

12. The device of claim 11, wherein said semiconductor device further comprises:
a substrate, supporting said rigid sensing area and said control electronics area; and

13. The device of claim 12, wherein said semiconductor device further comprises:
a first conductive line disposed over said electrically insulating layer; and
a contact coupled with said first conductive line and said substrate.

14. The device of claim 13, wherein said semiconductor device further comprises:
a first dielectric layer disposed over said first conductive line and said electrically insulating layer; and
a second conductive line disposed over said first dielectric layer.

15. The device of claim 14, wherein said semiconductor device further-comprises a first via coupled with said first dielectric layer and said first conductive line.

16. The device of claim 15, wherein said semiconductor device further comprises a second dielectric layer disposed over said first dielectric layer and said second conductive line.

17. A semiconductor device for biometric identification, comprising:
a rigid sensing area, said rigid sensing area including a capacitor plate;
a control electronics area, said control electronics area including a circuit device; and
at least one dielectric layer disposed in both said control electronics area and said sensing area, the dielectric layer including an etched region above said circuit device;
wherein said rigid sensing area and said control electronics area do not cross over, except where said capacitor plate is electrically coupled to said circuit device.

18. The device of claim 17, wherein said semiconductor device further comprises:
a substrate; and
an electrically insulating layer disposed over said substrate.

19. The device of claim 18, wherein said semiconductor device further comprises:
a first conductive line disposed over said electrically insulating layer; and
a contact coupled with said first conductive line and said substrate.

20. The device of claim 19, wherein said semiconductor device further comprises:
a first dielectric layer disposed over said first conductive line and said electrically insulating layer; and
a second conductive line disposed over said first dielectric layer.

21. The device of claim 20, wherein said semiconductor device further comprises a first via coupled with said first dielectric layer and said first conductive line.

22. The device of claim 21, wherein said semiconductor device further comprises a second dielectric layer disposed over said first dielectric layer and said second conductive line.

23. The semiconductor device of claim 17, further comprising a passivation layer disposed over said capacitor plate and said circuit device, said passivation layer configured to receive a finger at a first surface of said semiconductor device, the first surface above said capacitor plate, and further configured to avoid the finger at a second surface of said semiconductor device, said second surface above the circuit device.
